(19) United States
(12) Patent Application Publication
(10) Pub. No.: US 2016/0373154 A1
(43) Pub. Date: Dec. 22, 2016

(54) Electronic Device Housing Utilizing A Metal Matrix Composite

(71) Applicant: II-VI Incorporated, Saxonburg, PA (US)

(72) Inventors: Giovanni Barbarossa, Saratoga, CA (US); Michael K. Aghajanian, Newark, DE (US)

(73) Assignee: II-VI Incorporated, Saxonburg, PA (US)

(21) Appl. No.: 15/175,840

(22) Filed: Jun. 7, 2016

Related U.S. Application Data
(60) Provisional application No. 62/180,097, filed on Jun. 16, 2015.

(51) Int. Cl. H04B 1/3888; H04M 1/02; H05K 5/00; H05K 5/03; C22C 29/06; H05K 5/04

(52) U.S. Cl. CPC H04B 1/3888; C22C 29/065; H05K 5/04; H05K 5/0086; H05K 5/03; H04M 1/0202

(57) ABSTRACT

A housing used for electronic devices includes a structural frame element formed of a metal matrix composite (MMC) for providing improved stiffness over other materials currently in use. The MMC is a metal matrix (formed of a material such as aluminum), with a reinforcing material (such as a glass fiber or ceramic) dispersed within the metal matrix. The composition of the reinforcing material, as well as the ratio of reinforcing material to metal, define the stiffness (resistance to bending) and/or strength (resistance to breaking) achieved, and various compositions may be used for different housings, depending on the use of the electronic device. The element may be configured as a structural frame member, or may be embedded within another material forming the structural frame element. In another embodiment, the MMC may be used to form various components of the complete housing, including the enclosure itself.

### CROSS REFERENCE TO RELATED APPLICATIONS

This application claims the benefit of U.S. Provisional Application Ser. No. 62/180,097, filed Jun. 16, 2015 and herein incorporated by reference.

### TECHNICAL FIELD

The present invention relates to a housing used for electronic devices and, more particularly, to a housing including at least a frame component formed of a metal matrix composite (MMC) material for providing improved stiffness over other lightweight materials currently in use.

### BACKGROUND

Many types of electronic devices that are used for communication and/or entertainment purposes are relatively small; that is, configured to be “hand held”, portable, or mobile devices. While needing to be sufficiently rugged to protect the complex electronics and communication components forming such a device, its outer housing (also referred to at times as a chassis, case, or shell) also needs to be relatively thin and lightweight for comfort and convenience of the user.

In most cases, the outer housing includes a structural element (referred to at times herein as a “frame”) that is used to provide resistance to mechanical damage from bending (for example). Steel is an attractive construction material for this structural frame element, since it exhibits a high stiffness. However, steel also has a high density, which leads to high component mass. Aluminum is also an attractive construction material for the structural frame, since its density is significantly lower than steel. However, aluminum exhibits a very low stiffness, which leads to unwanted bending. Bending of an electronic device can lead to catastrophic damage. Indeed, there have been reports of consumer complaints regarding bending problems associated with these lightweight housings.

Besides the needs for lightweight, yet durable, consumer electronics housings, various commercial electronic devices (particularly, military devices) also derive benefits from a housing that provides the desired degree of stiffness/strength for a wide range of environmental factors, yet is lighter in weight than housings made of steel or other high-strength materials.

### SUMMARY OF THE INVENTION

The needs of the prior art are addressed by the present invention, which relates to a housing used for electronic devices and, more particularly, to a component of the housing that is formed of a metal matrix composite (MMC) for providing improved stiffness over other lightweight materials currently in use.

In accordance with the present invention, an electronic device housing is formed to include a structural element comprised of an MMC material. The element may be configured as a structural frame member, or may be embedded within another material forming the frame. In another embodiment, the MMC may be used to form various components of the complete housing, including the enclosure itself. For the purposes of the present invention, as long as an MMC is utilized as at least a portion of a structural frame member, the desired improvement in housing stiffness is provided.

It is an aspect of the present invention that the utilization of an MMC-based structural frame elements provides both an increased stiffness (i.e., resistance to elastic deformation, such as bending) without an increase in mass, as well as an increase in strength (i.e., resistance to plastic deformation and/or breakage), where the latter quality is particularly provided by the utilization of an MMC that comprises a high aspect ratio of the reinforcement material (e.g., fibers or ceramics) with respect to the metal matrix constituent.

The MMC-based structural frame element of the present invention may be incorporated within a wide variety of “hand-held” electronic devices including, but not limited to, cell phones, tablets, pads, etc. The specifics of the device itself are not germane; as long as there is a need to maintain a stiffness in the device's housing while not unduly increasing the weight of the device, the MMC frame element of the present invention provides a solution. Indeed, as mentioned above, the utilization of an MMC-based frame element is also useful in a variety of commercial and/or military components (for example, as a chassis).

One exemplary embodiment of the present invention takes the form of an electronic device housing comprising at least one structural frame element comprising a metal matrix composite (MMC) material.

Another embodiment comprises housing for a hand-held electronic device comprising at least one structural frame element comprising a metal matrix composite (MMC) material.

Other and further embodiments and aspects of the present invention will become apparent during the course of the following discussion, and by reference to the accompanying drawings.

### BRIEF DESCRIPTION OF THE DRAWINGS

Referring now to the drawings, where like numerals represent like parts in several views:

FIG. 1 illustrates an exemplary MMC structural frame element, configured for use in a cell phone housing, formed in accordance with the present invention;

FIG. 2 shows another embodiment of the present invention, in this case comprising an MMC insert embedded within a cell phone structural frame element formed of another material;

FIG. 3 is a cut-away view of the configuration of FIG. 2 taken along line 3-3;

FIG. 4 is another cut-away of the configuration of FIG. 2, this view taken along line 4-4 of FIG. 2;

FIG. 5 illustrates another embodiment of the present invention, in this case comprising an MMC-based structural frame element disposed within a cell phone housing structure;

FIG. 6 illustrates an alternative configuration of an MMC structural frame element formed in accordance with the present invention;

FIG. 7 illustrates yet another alternative configuration of an MMC structural frame element;

FIG. 8 illustrates another embodiment of the present invention, in this case forming a majority of an electronic device housing of an MMC material; and

FIG. 9 illustrates an exemplary electronic device chassis whr at least a portion of the chassis is formed of an MMC material.

### DETAILED DESCRIPTION

In general, a metal matrix composite (MMC) is a material with at least two constituent parts—one being a metal and the other being a ceramic or organic compound (or even a different type of metal). MMCs are made by dispersing a reinforcing material into a metal matrix. The matrix itself is a continuous phase into which the reinforcement is embedded. In one exemplary design, carbon fiber is used as the reinforcing material with an aluminum matrix, creating composites exhibiting low density and high strength. In another example, an MMC is made of aluminum (Al) impregnated with ceramic particles, such as silicon carbide, to form Al/SiC MMCs. Instead of silicon carbide, aluminum oxide may be used to form Al/Al₂O₃ MMCs. Depending on the metal (matrix) type, reinforcement chemistry, reinforcement shape (e.g., particles, fibers, whiskers, etc.) and the ratio between the two components, a range of useful properties can be engineered. Indeed, the key properties/characteristics of MMCs that can be tailored include density, stiffness, ductility (elongation), strength, machinability, thermal behavior, and ability to be “surface treated” (that is, painted, anodized, plated, etc.).

For the purposes of the present invention, it is desirable to use such an MMC material in an electronic device housing so as to render the device essentially “unbendable”, while remaining lightweight and thin. In this context, unbendable means that the housing should be as stiff (i.e., rigid) as possible. It is to be noted that the utilization of a sufficiently stiff housing thus results in providing a whole electronic device that is also rigid. A measure of the stiffness of a material is provided by Young's modulus, which is measured in Pascal (Pa) or Newtons/m² (in higher orders of magnitude, defined as GigaPascal—GPa or kilo-Newton/mm²).

An exemplary Young's modulus on the order of 125 GPa is acceptable for present purposes of providing a stiff structural frame for electronic device housings, and is associated with an Al—SiC MMC having 30% SiC. The Al—SiC MMC material exhibits a density on the order of aluminum, but with a stiffness of 125 GPa is much more rigid than aluminum (typical stiffness of Al is on the order of 70 GPa). This material can be formed using many different processes, such as but not limited to, die-casting, extrusion, forging, thixoforming, power metallurgy, and the like. Other materials, such as an Al—SiC MMC having 55% SiC (exhibiting a Young's modulus equivalent to stainless steel on the order of 200 GPa), may also be used. It is to be understood that there are a variety of different MMC materials that may be used for the purposes of the present invention, and the scope of the invention is not intended to be limited to any specific material, or class of materials. The metal matrix may be reinforced with any acceptable type of carbon fiber, ceramic fiber, ceramic particle or even another type of metal, where the type (and percentage) of reinforcement selected will result in an MMC with specific characteristics in terms of stiffness and strength.

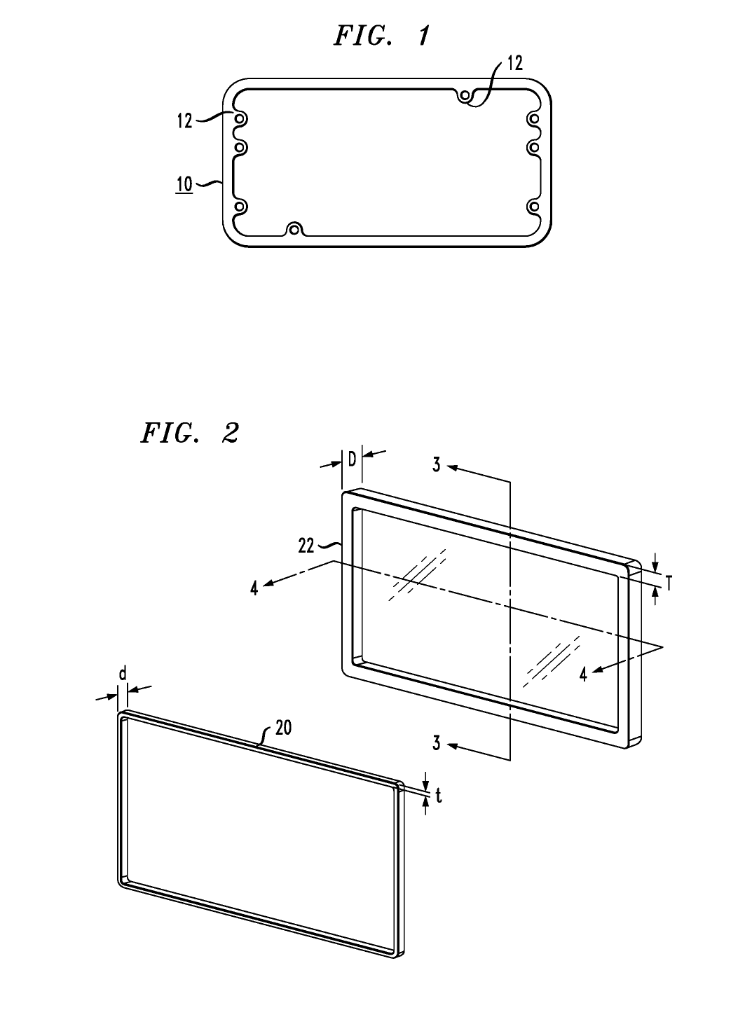

FIG. 1 illustrates an exemplary cell phone structural frame 10 formed of an MMC component in accordance with the present invention. In one particular embodiment, MMC structural frame 10 may be produced from a silicon carbide, particle-reinforced aluminum alloy MMC with a reinforcement content of 55 vol. % (Al/SiC-55 p), as mentioned above. MMC frame 10 as shown in FIG. 1 can be fabricated by producing a slurry of SiC particles and molten Al, followed by casting and machining. The casting and machining steps are used to form MMC frame 10 to exhibit the desired dimensions (width, length, thickness, cross-section and the like), as well as include the various features (shown as elements 12 in FIG. 1) necessary for use as a cell phone frame that connects to an outer housing. The following table includes a comparison of the relevant properties of MMC frame 10, when compared to prior art steel and aluminum frames.

| Construction Material | Component Mass (g) | Material Stiffness (GPa) |
|---|---|---|
| Aluminum (grade 6061) | 12.4 | 69 |
| Steel (grade 304 SS) | 36.9 | 193 |
| Al/SiC-55p MMC | 13.5 | 200 |

As produced, MMC frame 10 is found to exhibit a combination of the desired properties for an electronic device structural frame: low mass (similar to aluminum) and high stiffness (similar to steel). Additionally, the relative strength (in terms of resistance to plastic deformation and/or breakage) of MMC frame 10 can be enhanced by using a formulation that contains a high aspect ratio reinforcement component (e.g., fiber, platelet, or the like).

As will be described in detail below, there are a variety of different configurations that may incorporate the inventive MMC-based structural frame element. Moreover, it is also possible to utilize more than one MMC-based element, where each comprises a different composite to tailor the structure to the specific needs of a specific device. Additionally, the MMC frame element itself may be formed to exhibit variations in composition, thickness, width, cross-section, and the like across its length; again, as required for a specific application. These and other features of the inventive MMC-based electronic device housing will be described in detail below.

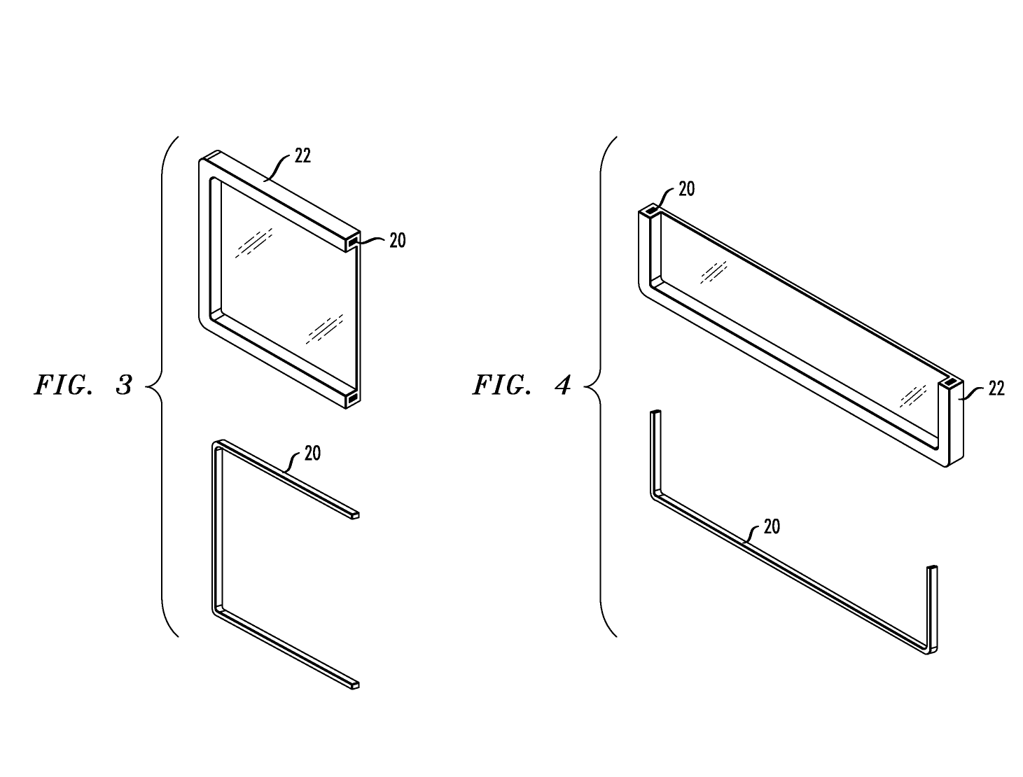

FIG. 2 illustrates an exemplary MMC insert 20 to be included as a stiffening component embedded within another material utilized to form an electronic device frame, shown as framing component 22 in FIG. 2. MMC insert 20 is shown as a frame of MMC material (in this specific case, rectangular in form), and configured to have a desired thickness t and depth d. The specific dimensions are selected in this case such that insert 20 can be completed embedded within the larger framing component 22 having overall dimensions (D,T), as shown. While MMC insert 20 may be completely embedded within framing component 22, this is not a requirement, and a portion of insert 20 may remain visible in the final product.

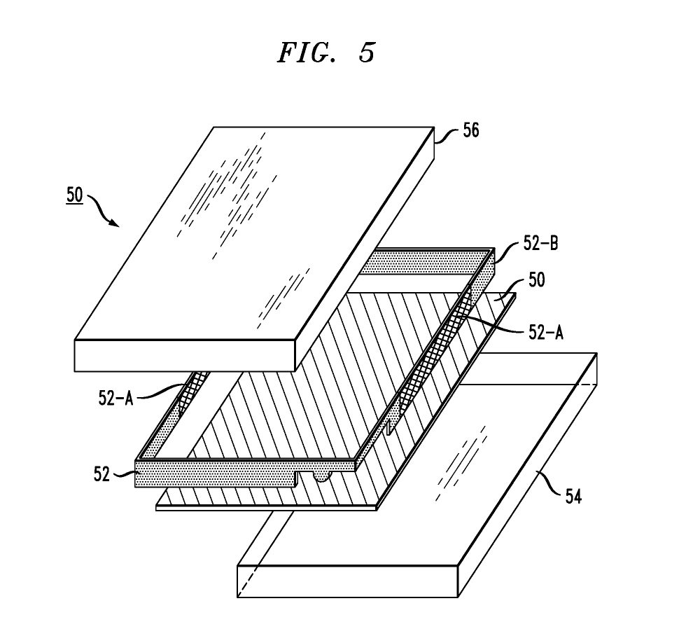

FIG. 3 is a cut-away view of framing component 22 illustrating the placement of MMC insert 20 within component 22, taken along line 2-2 of FIG. 2 (with a view of the configuration of MMC insert 20 also shown). In this exemplary embodiment, MMC insert 20 is completely embedded within framing component 22. FIG. 4 is another cut-away view of MMC insert 20 within component 22, taken along line 3-3 of component 22 as shown in FIG. 2.

In accordance with the present invention, the inclusion of a sufficiently stiff, rigid MMC insert 12 within the conventional lightweight material used as the structural framing element for an electronic device housing (e.g., aluminum or an aluminum alloy, magnesium or a magnesium alloy, or other) allows for the overall housing itself to be considerably stiffer, without requiring the housing to be any thicker or heavier. This is due to the fact that MMCs are much stiffer than aluminum (in fact, certain MMCs may be stiffer than steel), yet have a weight similar to aluminum. Moreover, inasmuch as the insert provides a sufficient stiffness for the overall electronic device housing, it is possible to form the housing itself of a relatively low cost, non-metallic, lightweight material (e.g., plastic, rubber, polymer, etc.). While providing an improved stiffness (which may be defined as resistance to elastic deformation, such as bending), specific compositions of an MMC may be selected that also provide an improvement in strength when compared to prior art housings (where in this context “strength” is defined as resistance to plastic deformation and/or breakage). For example, an MMC with high aspect ratio reinforcement material with respect to the metal matrix is known to provide this resistance to plastic deformation.

For the embodiment shown in FIGS. 2-4, MMC insert 20 may be embedded within electronic device structural frame component 22 using any suitable technique. For example, conventional molding, die-casting, mechanical assembly, soldering, brazing or roll forming processes may be used. In one exemplary configuration, MMC insert 20 may be embedded during the die-casting process currently employed to create the aluminum casing. Alternatively, framing component 22 may be formed as a two-part housing (e.g., a “clam shell” configuration), with MMC insert 20 positioned within one part of the housing, and the two parts then joined together.

FIG. 5 illustrates another embodiment of the present invention, in this case where an MMC component is not encased within another material; instead, used as the structural frame element itself. As shown, electronic device housing 50 is formed to include a structural frame element 52 consisting only of an MMC component. Here, MMC structural frame element 52 (similar to the structural frame element 10 described above in association with FIG. 1) is utilized as the frame for housing 50, where housing 50 further includes a base 54 and a lid 56, with a conductive substrate 58 disposed in place between structural frame element 52 and base 54. In contrast to the embodiment described above, the MMC component is not embedded within another material (that is, used as an “insert”), but forms the actual frame itself.

As shown in FIG. 5, MMC structural frame element 52 includes regions of different height, as may be necessary to accommodate external components that may need to couple to an enclosed electronic device. Further, in accordance with the present invention, it is possible to use more than one MMC component to form the frame. For example, suppose it is desired to create housing 50 with very rigid sidewalls—but not necessarily rigid in the corners or along the shorter end walls. In this case, a metal matrix composite with an extremely high material stiffness may be used to form sidewall sections 52-A, as shown in FIG. 5, with a material of lesser stiffness (and perhaps lighter weight and/or expense) used to form the remaining sections of the frame element (shown as sections 52-B in FIG. 5). Advantageously, the ability to use multiple, different MMC materials allows for a wide variety of electronic device packaging requirements to be met. Moreover, while not explicitly shown in FIG. 5, it is also possible to easily modify the cross-sectional area of MMC frame 52, providing identified regions with an increased thickness where necessary to provide a local increase in stiffness.

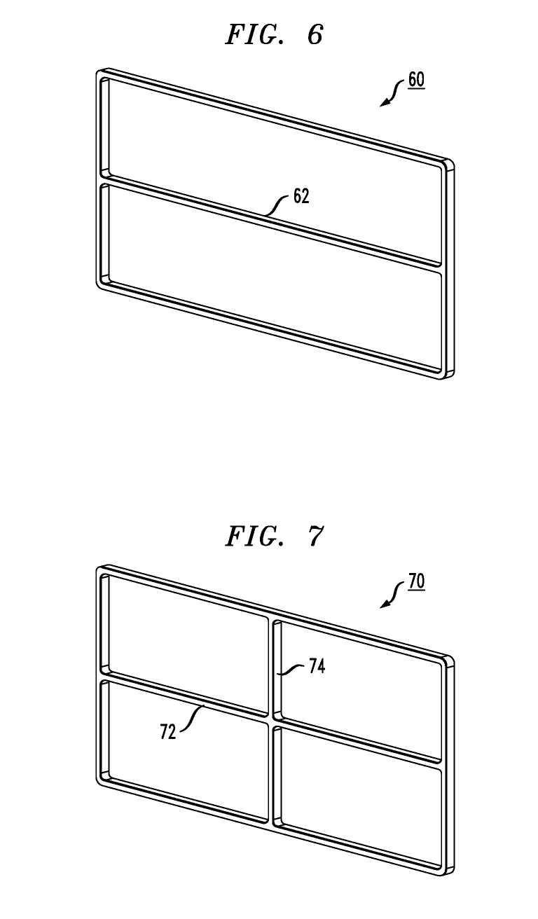

While the various MMC-based structural elements described thus far take the shape of a single rectangle, it is to be understood that various other topologies for the MMC-based structural element may be utilized, particularly when desired to increase the rigidity and/or strength of the structure (such as for military applications, for example). FIG. 6 illustrates an exemplary MMC structural element 60 that is formed as a pair of cells, with the addition of a wall 62 along the length of the element providing extra rigidity and limiting rotational motion. FIG. 7 illustrates another exemplary MMC-based structural element, in this an MMC-based element 70 that is formed as a “four cell” configuration, with cross-members 72 and 74 added to improve stiffness and limit rotational motion in both planes of the surface.

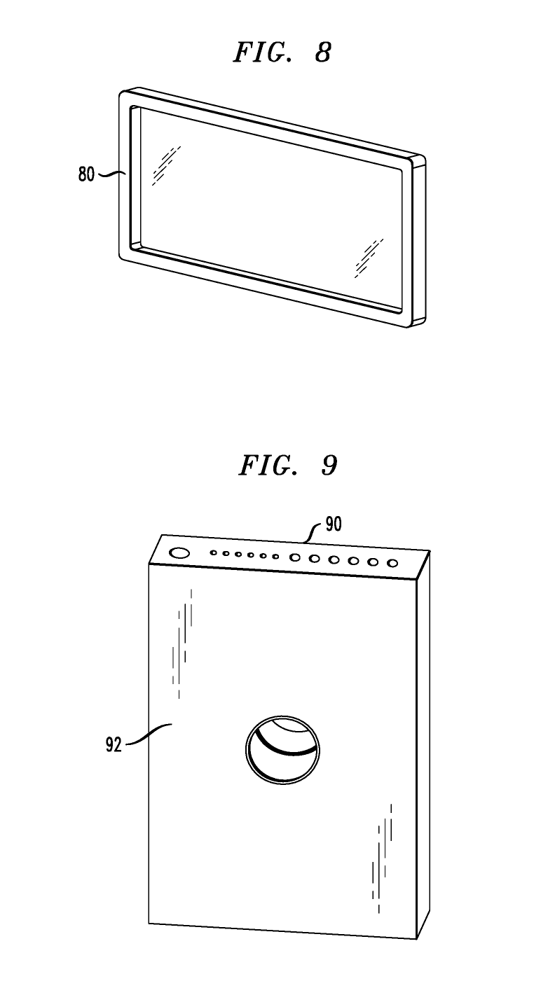

As mentioned above, an MMC-based structural element of the present invention may also take the form of an electronic device housing itself. FIG. 8 illustrates an exemplary electronic device housing 80, where the housing itself is formed of MMC material 82. By controlling the specific materials used in its formation, as well as the ratio of the materials, a desired Young's modulus factor can be provided while still taking the form of a relatively thin and lightweight housing.

While useful in creating structural frame elements for “hand-held” electronic devices, MMC-based structural components may also find use, in accordance with the present invention as housings or enclosures for a variety of commercial or military electronic systems. Indeed, it is considered that various military systems where there is a need to maintain strength and rigidity with the lightest weight as possible, are potential uses. FIG. 9 illustrates an exemplary electronic device chassis 90, where at least a portion 92 of chassis 90 is formed of an MMC material. In this case, the MMC housing can provide two different functions. First, the MMC gives enhanced stiffness at low mass, as described in detail above. Second, since most MMCs are high thermal conductivity materials (such as, for example, Al/SiC), they can provide a thermal management function and help pull heat away from heat-generating electronic devices.

Without limitation, the following is a listing of specific advantages and features of the present invention:
the cross-section of the MMC insert may be designed to provide maximum stiffness for a specific application
the MMC insert may be partially exposed (i.e., not completely embedded within the housing)
the MMC insert may be “shaped” to improve the grip between the insert and the surrounding housing
the MMC insert may be formed to exhibit a variable cross section—thicker in areas where stiffness is required and thinner in other areas (reducing the overall weight of the housing)
the MMC insert may include plates of MMC material
more than one MMC insert may be used within the housing, each may include a different composition and/or dimensions
the MMC material may be used to form the complete housing itself, without needing to be embedded within another material
the reinforcement component of the MMC material may vary (in percentage) by location in the insert (i.e., higher content of reinforcement component where maximum stiffness is required and lower content where subsequent machining or ductility are required)
the MMC material may be formed with a surface skin of Al alloy to enhance surface coating (e.g., by anodizing and/or machining)
the MMC may be formed to exhibit other specialized properties beyond an increase in stiffness, such as an enhancement in strength (defined as resistance to plastic deformation and/or breakage), with the use of an MMC that contains a high aspect ratio reinforcement constituent
the MMC may be used to provide more than one function for the electronic device, for example: (1) stiffening the device to resist bending, owing to its Young's modulus, and (2) thermal management (e.g., removal of heat from electronics) owing to its high thermal conductivity.

The above-described embodiments of the present invention are presented as being illustrative only of principles of the invention. Various modifications and changes can be made by those skilled in the art without departing from the scope and spirit of the present invention.

What is claimed is:

1. An electronic device housing comprising
at least one structural element comprising a metal matrix composite (MMC) material.

2. The electronic device housing as defined in claim 1 wherein the at least one MMC-based structural element includes at least one fiber-reinforced MMC material.

3. The electronic device housing as defined in claim 1 wherein the at least one MMC-based structural element includes at least one ceramic-reinforced MMC material.

4. The electronic device housing as defined in claim 3 wherein the at least one ceramic-reinforced MMC material comprises Al—SiC.

5. The electronic device housing as defined in claim 1 wherein the at least one structural element comprises a single MMC-based structural element.

6. The electronic device housing as defined in claim 1 wherein the at least one structural element comprises a plurality of MMC-based structural elements.

7. The electronic device housing as defined in claim 6 wherein each MMC-based structural element comprises a different composition of constituents forming each element.

8. The electronic device housing as defined in claim 6 wherein each MMC-based structural element comprises a like composition of constituents, with each having a different aspect ratio of reinforcement constituent.

9. The electronic device housing as defined in claim 1 wherein the at least one MMC-based structural element comprises a chassis for housing electronic devices.

10. A housing for a hand-held electronic device comprising
at least one structural element comprising a metal matrix composite (MMC) material.

11. The housing as defined in claim 10 wherein the at least one structural element comprises an MMC-based insert embedded with a frame component.

12. The housing as defined in claim 10 wherein the housing further comprises
a base,
an electrically conductive substrate, and
a lid, with the at least one structural element disposed between the conductive substrate and the lid.

13. The housing as defined in claim 12 wherein the at least one structural element comprises an MMC-based frame disposed between the electrically conductive substrate and the lid.

14. The housing as defined in claim 13 wherein the MMC-based frame includes one or more cross-members.

15. The housing as defined in claim 12 wherein the base and the lid comprise MMC materials.

16. The housing as defined in claim 15 wherein the same MMC material is utilized for the lid, base and structural element.

17. The housing as defined in claim 15 wherein a first MMC material is utilized for the lid and base, and a second MMC material is utilized for the structural element.

18. The housing as defined in claim 15 wherein the hand-held device comprises a cell phone device.

19. The housing as defined in claim 12 wherein the MMC-based structural element is embedded within an aluminum frame component.

20. The housing as defined in claim 6 wherein the at least one MMC-based structural element comprises portions of different thickness, cross-sectional area or width.

21. The electronic device housing as defined in claim 1 wherein the MMC-based structural element is designed to provide a dual function of stiffening and thermal management.
